(19) United States
(12) Patent Application Publication
(10) Pub. No.: US 2021/0305479 A1
(43) Pub. Date: Sep. 30, 2021

(54) Efficient thermoelectric power generation

(71) Applicant: Mathew Mark Zuckerman, Carbondale, CO (US)

(72) Inventor: Mathew Mark Zuckerman, Carbondale, CO (US)

(21) Appl. No.: 16/602,407

(22) Filed: Sep. 30, 2019

(51) Int. Cl. H01L 35/22; H01L 35/32

(52) U.S. Cl. CPC H01L 35/225; H01L 35/32

(57) ABSTRACT

A system and method for efficient thermoelectric power generation by combining natural gas as a thermal source with emitters, such as Silicon Carbide, highly-doped Silicon Carbide semiconductor material as cells, harvesting of electric power through in situ formation of Graphene Carbon, and semiconductor materials. The system is can yield orders of magnitude greater power efficiency over thermoelectric power generation units used in space travel, by practicing the invention, natural gas, such as the 288.7 billion cubic currently wasted by the environmental damaging practice of flaring off, can be converted into useful electricity for transport over low-cost transmission line infrastructure rather than possible future high-cost pipelines. Also, by practicing the invention, households can be provided with standby power, power during natural disasters, such as hurricanes, by converting available natural or propane gas rather relying on generators with single digit efficiency.

### FIELD OF INVENTION

The present invention relates generally to energy conversion. More particularly, disclosed are methods and systems for adapting direct conversion of thermal to electrical energy. The conversion has applicability to widespread application, for instance, as a reliable system and method for long-term energy conversion in mission-critical space applications, terrestrial applications for capturing the energy in currently flared-off natural gas, generating stand-by power from natural and propane gas, and in other applications.

### BACKGROUND OF INVENTION

Russian and Soviet Russian thermoelectric technology has historically exceeded that of the United States. Russian thermoelectric technology powered Sputnik's beeping heard round the World: this first satellite was launched in October 1957. In World War II, while US soldiers powered their 2-way radios by hand-cranking dynos, the Russians used silent thermoelectric power units with a metallic voltaic cell heated by a kerosene lantern. Russia equipped more than 100,000 of its partisan soldiers with a unit delivering one to two watts of electric power, enough to operate a radio receiver. In space, 38 Russian and Soviet missions and 22 of the US missions have used thermoelectric power with Plutonium-238 radioisotope as the heat source, called the

Radioactive Power Supply (RPS). The RPS was found to produce such reliable power that the extension of the useful life of several missions in space has been accredited to this source of power.

The existence of the RPS was recently popularized in the feature film, The Martian, where the RPS was dug up and repurposed to heat the Land Rover. In the film, thermoelectric conversion efficiency is correctly stated as only 7 to 8%. This low efficiency of the RPS is of little concern in the primary mission because of the large amount of energy release by the radioisotope, and it is a huge advantage for the repurposed mission as portrayed in the film because 92% to 93% of the energy of the radioisotope goes to waste heat to make the Land Rover warm enough for a human.

Global Thermoelectric, a Canadian company, is reported to be the World's largest maker of commercially available Mobil Power Supplies (MPSs). The Company uses metal cells, made from Lead Telluride, that were developed by 3M Corporation for the Apollo Space Program in the 1960s. Their highest capacity unit, weighs 1,500 pounds, uses natural or propane gas as thermal energy source, and produces only one kilowatt at an efficiency comparable to that of RTE's used in space at only seven and eight-tenth percent (7.8%).

Thermoelectric Power. The same principles apply for the generation of electric power thermally, from heat, as apply for generation of electric power from light. The discoveries of three innovators provide the underpinning to understanding of thermal and photo electric effects. In 1821, Thomas Seebeck discovered that electric power is generated when two dissimilar metal rods, electrically connected in series at one end and electrically connected in parallel at the other end, are exposed to extremes in temperature: the thermal electric effect. In 1843, John-Charles Peltier discovered that Seebeck's process is reversible so that when a current is applied to the metal rods, cooling of one end relative to the other occurs.

If the hot ends of the n-type and p-type material are electrically connected and a load connected across the cold ends, the voltage produced by the Seebeck effect will cause current to flow through the load, generating electrical power. The electrical power produced is the product of the voltage and electrical current across the load. The temperature difference provides the voltage, but it is the heat flow that enables the current. A thermoelectric generator behaves much like an ideal voltage source with an internal resistance due largely to the resistance of the thermoelectric materials themselves. The voltage at the load is reduced from the open circuit voltage by Ohm's law, V=IR, thereby producing voltage drop due to internal resistance.

The efficiency of a generator depends not just on the power produced but also how much heat is provided at the hot end. The heat input is needed for the thermoelectric process (Peltier effect) as well as normal thermal conduction (Fourier's law) and is offset by the Joule heating in the device. The Fourier's law thermal conduction of the thermoelectric materials adds a thermal path from hot to cold that consumes some heat and reduces the efficiency. It can be shown that the maximum efficiency of a thermoelectric material depends on two terms. The first is the Carnot efficiency, for all heat engines cannot exceed Carnot efficiency. The second is a term that depends on the thermoelectric properties, the Seebeck coefficient, electrical resistivity, and thermal conductivity. These material properties all appear together and thus form a new material property which we call zT: The Thermoelectric Figure of Merit.

Graphene Carbon. Graphene is a two-dimensional hexagonal crystalline form of Carbon. Among its desirable properties is superconductivity, ballistic transport of electrons at room temperature along a 30-degree line of chirality. Graphene has a conductivity of 2.35×10³ Siemens per meter, which makes the Graphene an excellent conductor.

Graphene was first discovered by micro mechanical cleavage using stock tape to separate it from graphite. Graphite is the form of Carbon that is commonly found in hardware stores for use as a dry lock lubricant. Graphite, a sister to coal, is so abundant in the Earth's crust that the cost for this form of Carbon is measured in pennies per pound. Graphene is the hexagonal mono-crystalline form of Carbon and is coveted for its superconductive properties. Prior to the present invention, Graphene has been so costly to manufacture that the cost is measured in hundreds of dollars for a single gram ( 1/454^{th} of a pound). Successful methods for growing Graphene include chemical vapor deposition (CVD) on metal surfaces like Copper or Nickel. However, transferring the Graphene from metallic surfaces introduces mechanical strain that is damage prone.

Stranded Natural Gas and Stand-by Power Generation. In 2014, the U.S. flared-off 288.7 billion cubic feet of natural gas, worth $10 billion. This gas was wasted because of a lack of pipeline infrastructure for transport. Annually, there are over 200,000 portable generators sold in the United States to generate one to five kilowatts of electricity. These units, so bulky and heavy that hand trucks are often built-into the units to aid in making them portable, are used for stand-by power generation for outages that occur in natural disasters, such as hurricanes.

There is a need to invent an elegant solution that directly generates power on demand from combustible fuels, preferably low cost and abundant domestically-sourced natural gas, with the reliability and long useful life of an all solid-state device, to terrestrial applications that include the capture of the energy currently wasted as flared-off natural gas and generating stand-by power.

### SUMMARY OF THE INVENTION

With a knowledge of the state of the art and the limitations thereof, a principal object of embodiments of the present invention is to produce systems and methods for direct energy conversion cells that use as a source of energy the Earth's opacity spectrum that is otherwise filtered out and not available to terrestrial solar cells.

It is an object of embodiments of the present invention to provide a device that converts stranded natural gas, currently wasted by the environmental damaging practice of flaring off, into useful electricity, potentially for transport over low cost infrastructure of transmission lines rather than, for example, potential high cost pipelines.

It is a further object of embodiments of the present invention to provide a device that provides households with standby power during natural disasters by efficiently converting available natural or propane gas rather relying on bulky generators with single-digit efficiency.

It is a still further object of embodiments of the present invention to reduce the losses of energy by using Silicon Carbide as an emitter of a spectrum of energy that in turn is incident on a cell, such as a Silicon Dioxide cell, for direct conversion to electrical energy.

It is another and further object of embodiments of the present invention to produce devices with cells constructed with large lengths compared to narrow thicknesses, such as by using Silicon Carbide wafers that approach a 3,000:1 dimensional aspect ratio and favor efficient electrical generation by the Seebeck thermal electric effect rather than the Peltier cooling electric effect.

It is still a further object of embodiments of the present invention to provide heavy doped cells constructed, by way of example, from the subset of Silicon Carbide crystalline poly-types that are hexagonal, arranged in an alternating “p” and “n” configuration to provide Seebeck Coefficients of greater values than achievable by any known space metal material or semiconductor material.

It is another object of embodiments of the present invention to form conductive surfaces on the anode hot surface and the cathode cold surface of the Silicon Carbide by sublimation of silicon to form the hexagonal crystalline carbon, Graphene, with superconductive conductivity at room temperature at a chirality of 30 degrees.

These and further objects, advantages, and details of the present invention will become obvious not only to one who reviews the present specification and drawings but also to those who have an opportunity to experience an embodiment of the systems and methods for highly efficient thermoelectric power generation disclosed herein in operation. However, it will be appreciated that, although the accomplishment of multiple of the foregoing objects in a single embodiment of the invention may be possible and indeed preferred, not all embodiments will seek or need to accomplish each potential advantage and function. Nonetheless, all such embodiments should be considered within the scope of the present invention.

The systems and methods disclosed herein seek to achieve an order of magnitude increase in thermal conversion over thermal energy generators used in space. The systems and method can include, without limitation except as set forth expressly in the claims, one or more of: 1) constructing cells with large length to narrow thickness that approach, for example, a 3,000:1 aspect ratio; 2) supplying energy incident on the cells, such as by combustion of natural gas equal to the Earth's opacity spectrum that is otherwise filtered out and not available to terrestrial solar cells; 3) using hexagonal crystalline Silicon Carbide semiconductor materials as the emitter of a spectrum of energy to create a 1:1 spectral matching as the energy is in turn incident on Silicon Carbide semiconductor material as cells; 4) providing heavy doped cells constructed from the subset of Silicon Carbide crystalline poly types that are hexagonal, arranged in an alternating “p” and “n” configuration; and 5) forming conductive surfaces on the anode hot surface and the cathode cold surface of the Silicon Carbide material cells, such as by sublimation of the silicon to form the hexagonal crystalline carbon, Graphene, with superconductive conductivity at room temperature at a chirality of 30 degrees, to connect multiple devices in series and parallel cells that are in turn connected to a terminal thereby forming a power supply.

The disclosed system and method employ a novel and non-obvious combination of elements to produce a solid state direct energy conversion device that seeks to achieve an order of magnitude increase in thermal conversion efficiency over the Radioactive Power Supply (RPS), which is fueled by the Plutonium-238 radio-isotope and used metal cell materials.

In one practice of the invention, the order of magnitude increase in thermal conversion efficiency over Radioactive Power Supply (RPS) is sought to be achieved by combining the following elements:
1. Favoring the electrical-generating Seebeck thermal electric effect rather than the Peltier cooling electric effect by a device with cells constructed with large length to narrow thickness, such as by using Silicon Carbide wafers that approaching a 3000:1, dimensional aspect ratio;
2. Using, as a source of energy, the Earth's opacity spectrum that is otherwise filtered out and not available to terrestrial solar cells, the energy being available in the spectrum from the combustion of natural gas, reducing the losses of energy by using hexagonal crystalline Silicon Carbide semiconductor materials as the emitter of a spectrum of energy, to create a 1:1 spectral matching as the energy that is in turn incident on the cell for direct conversion to electrical energy;
3. Employing, best engineering techniques (BET) for utilizing the thermal electric effects, such as by providing heavy doped cells, constructed from the subset of Silicon Carbide crystalline poly-types that are hexagonal, arranged in an alternating “p” and “n” configuration to provide a Seebeck Coefficient of greater values than achievable by RPS metallic cells or un-doped semiconductor cells. BET are also employed, for instance, by forming conductive surfaces on the anode hot surface and the cathode cold surface of the Silicon Carbide, by sublimation of the Silicon, to form the hexagonal crystalline carbon, Graphene, with superconductive conductivity at room temperature at a chirality of 30 degrees, to electrically connect multiple devices into chains of cells in series and in parallel that are in turn connected to terminal forming a power supply.

One will appreciate that the foregoing discussion broadly outlines the more important goals and features of the invention to enable a better understanding of the detailed description that follows and to instill a better appreciation of the inventor's contribution to the art. Before any embodiment or aspect thereof is explained in detail, it must be made clear that the following details of construction and illustrations of inventive concepts are mere examples of the many possible manifestations of the invention.

### BRIEF DESCRIPTION OF THE DRAWINGS

To further clarify the above and other advantages and features of the present invention, a more particular description of the invention will be rendered by references to specific embodiments thereof, which are illustrated in the appended drawings. It will be understood that these drawings depict only embodiments of the broader invention disclosed herein and are, therefore, not to be limiting of its scope.

The invention will be described and explained with additional specificity and detail through reference to the accompanying drawings in which:

FIG. 1 is a diagram of the geometry of two dissimilar materials required to practice

Seebeck's Effect to generate electric power directly;

FIG. 2 is a chart of the Seebeck Effect and associated electric properties of Metal,

Semiconductor material, and Heavy Doped Semiconductors;

FIG. 3 is a chart of the Spectrum of Solar Radiation on Earth;

FIG. 4 is a chart of the Spectrum from the Combustion of a Hydrocarbon;

FIG. 5 is a chart of the Spectrum of Silicon Carbide Radiated as a function of temperature;

FIG. 6 is a depiction of characteristics of Hexagonal Crystalline poly types of Silicon

Carbide in comparison to other indirect materials;

FIG. 7 is a depiction of the characteristics of poly types commercially available as Silicon

Carbide wafers; and

FIG. 8 provides perspective, top plan, and schematic views of an embodiment of the thermoelectric power generation system disclosed herein.

### DETAILED DESCRIPTION OF PREFERRED EMBODIMENTS

The systems and methods for thermoelectric power generation disclosed herein are subject to a wide variety of embodiments. However, to ensure that one skilled in the art will be able to understand and, in appropriate cases, practice the present invention, certain preferred embodiments of the broader invention revealed herein are described below and shown in the accompanying drawing figures.

By way of further background, thermoelectric power generation dates to 1821 when Thomas Seebeck discovered that electric power is generated when two dissimilar metal rods are connected at hot ends thereof and electrically connected in parallel at cold ends thereof The present invention combines the replacement of solar energy with the energy of natural gas as a thermal source. In one aspect, photovoltaic cells with highly doped Silicon Carbide semiconductor material cells are sized to a highly favorable ratio, such as 1:3,000. Further, a coordination of thermally activated infrared energy spectrum optimizes the spectrum incident on the cells by constructing an emitter from the same poly type of Silicon Carbide as the cell. Harvesting of electric power can be achieved by in situ formation of Graphene Carbon and electric connection by materials that exhibit superconductive at room temperature.

Maximizing the Seebeck Coefficient. The first unexpected aspect of the present invention is that the merit of materials, such as can be measured by the Seebeck coefficient a in μV per degree Kelvin (also per degree Centigrade), can be the very desirable maximum when using only one semiconductor material and doping material as a p-type and the other n-type.

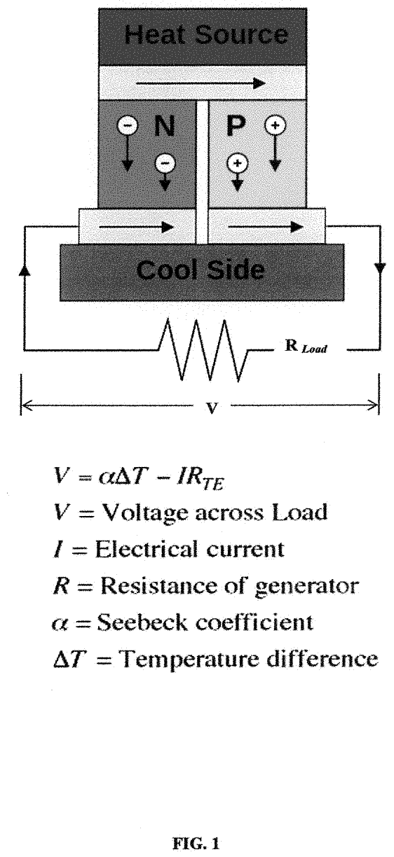

FIG. 1 diagrams the geometry of two dissimilar materials required to practice the Seebeck Effect to generate electric power directly. The present invention can utilize, for example, Silicon Carbide as a material with p-type doping to produce one of the dissimilar materials and n-type doping to produce the other dissimilar material. The n-type doping materials can, for example, be Nitrogen or Phosphorus, and p-type doping materials could, for instance, be Beryllium, Boron, Aluminum, or Gallium.

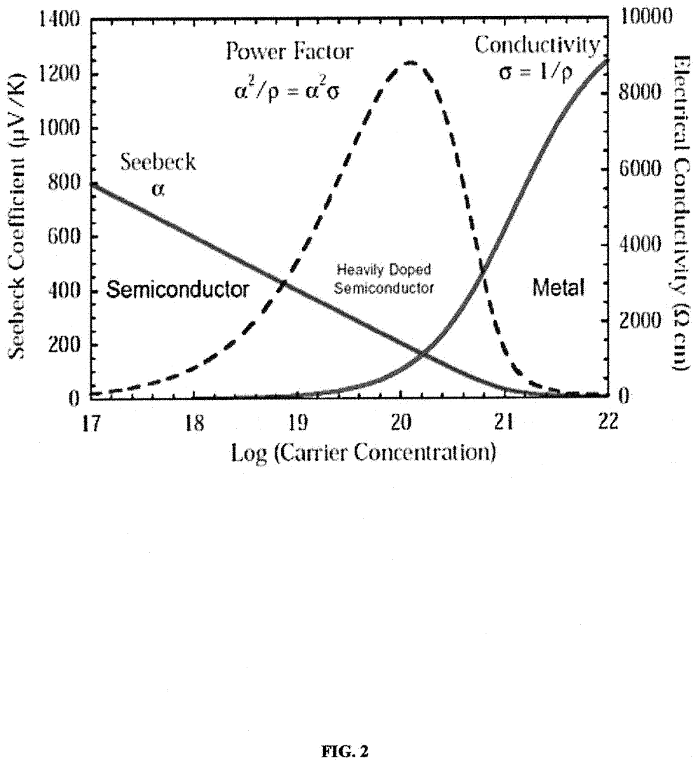

FIG. 2 shows the Seebeck Effect and associated electric properties of Metal, Semiconductor and Heavy Doped Semiconductors. Exemplary of the metals and metal compounds charted on the right portion of FIG. 2 with low Seebeck coefficients include the compound Lead Telluride that produces a low energy efficiency of seven and eight-tenths percent (7.8%). The present invention can exploit heavy doped semiconductors as charted in the center of FIG. 2 that have peak values of Seebeck coefficient greater than the values associated with either metals or semiconductors without doping. The result is that embodiments of the present invention using heavy doped Silicon Carbide are calculated to achieve 75% efficiency, an order of magnitude increase in power efficiency over that achieved by RTEs used in space.

Optimizing the Energy Spectrum Incident on the Thermoelectric Cell. A second unexpected aspect of the present invention is that the loss in Solar Spectrum that results from the absorption as it moves through the atmosphere is duplicated by the spectrum from the combustion of hydrocarbons and by impinging this combustion of hydrocarbon energy spectrum onto Silicon Carbide. An energy spectrum is emitted that is efficiently transmitted and received by the thermoelectric cells.

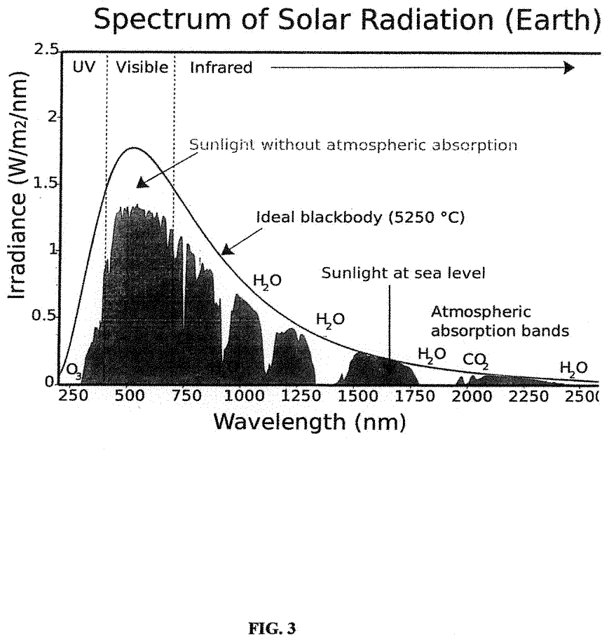

FIG. 3 shows the Spectrum of Solar Radiation on Earth. The Solar Spectrum that exists outside Earth is attenuated by the following components present in Earth's atmosphere: scattering due to air borne dust and aerosols; infrared absorption due to water vapor, Carbon Dioxide and Carbon Monoxide, and ultraviolet absorption due to ozone. The net effect is that the extraterrestrial spectrum's incident power density of 1,365 watts per square meter (W/m²) is reduced by 50% to an average incident power density over the surface of Earth of 691 W/m² (0.07 W/cm²).

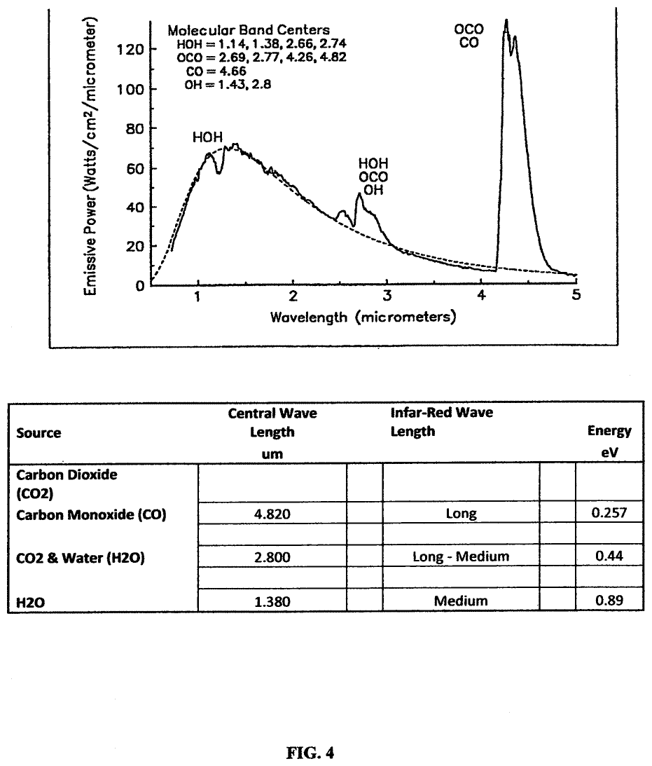

FIG. 4 shows the Spectrum from the Combustion of a Hydrocarbon. The table below the Spectrum identifies the peak discharges for the product of combustion. These products of combustion match up to the materials in the Earth's atmosphere that attenuate the solar spectrum. Below the Spectrum is a table that enumerates the materials and their associated characteristics. Among these materials are the primary Carbon compound, Carbon Dioxide (CO₂) and Carbon Monoxide (CO) that occurs at a wavelength of 4.66 um with incident power of 120 W/cm²/um. By integrating the area under the spectrum curve for CO₂/CO and comparing it to the solar spectrum, it is found that the Emission Power for this CO₂/CO peak is 367 times the emission power for entire solar spectrum (25.7 W/cm² versus the Sun's 0.07 W/cm²).

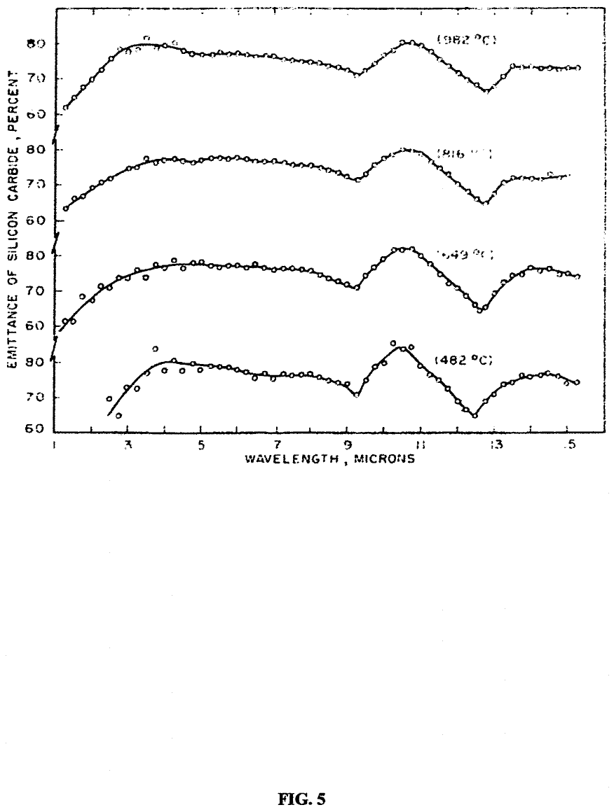

FIG. 5 shows the Spectrum of Silicon Carbide Radiated as a function of temperature. In embodiments of the present invention, the material of construction of the emitter and the cells are the same poly type of Silicon Carbide. As shown in FIG. 5, that spectrum emitted is uniform as to temperature over the infrared frequencies and varies in intensity as the temperature increases. Therefore, the spectrum of the Silicon Carbide serving as an emitter, albeit at a higher intensity associated with the higher temperature, with a uniform spectrum so that the spectrum put out by the emitter is equal to a favorable spectrum received by the cells.

Silicon Carbide Hexagonal Poly Types. A third unexpected aspect of embodiments of the present invention is that five poly types of Silicon Carbide, containing between 20 to 100% hexagonal crystalline, are of the same indirect character as Silicon (Si) and Gallium Arsenide (GaAs). Two of the poly types of Silicon Carbide are commercially available in wafer form at various diameters.

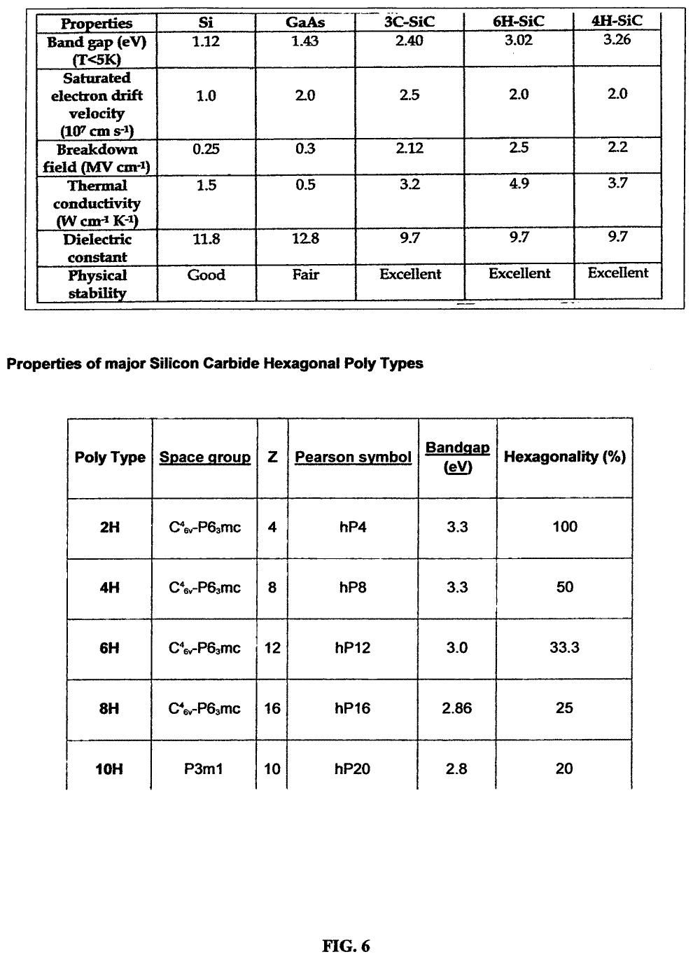

FIG. 6 shows some characteristics of Hexagonal Crystalline poly types of Silicon Carbide in comparison to other indirect materials. There are five poly types of Silicon Carbide that contain between 20% and 100% hexagonal crystalline structures: 2H, 4H, 6H, 8H and 10H. Of these, the commercially available poly types are 4H and 6 H Silicon Carbide. The characteristics of the poly types of Silicon Carbide 4H and 6H when compared to Silicon (Si) and Gallium Arsenide (GaAs) have superior ability to respond to infrared light with band gap in eV of 3.26 and 3.02 versus 1.12 and 1.43. Among the other more suitable characteristics for the present invention is that the poly types of Silicon Carbide 4H and 6H when compared to Silicon (Si) and Gallium Arsenide (GaAs) demonstrate thermal conductivity in W/cm K of 3.7 and 4.0 versus 1.5 and 0.5.

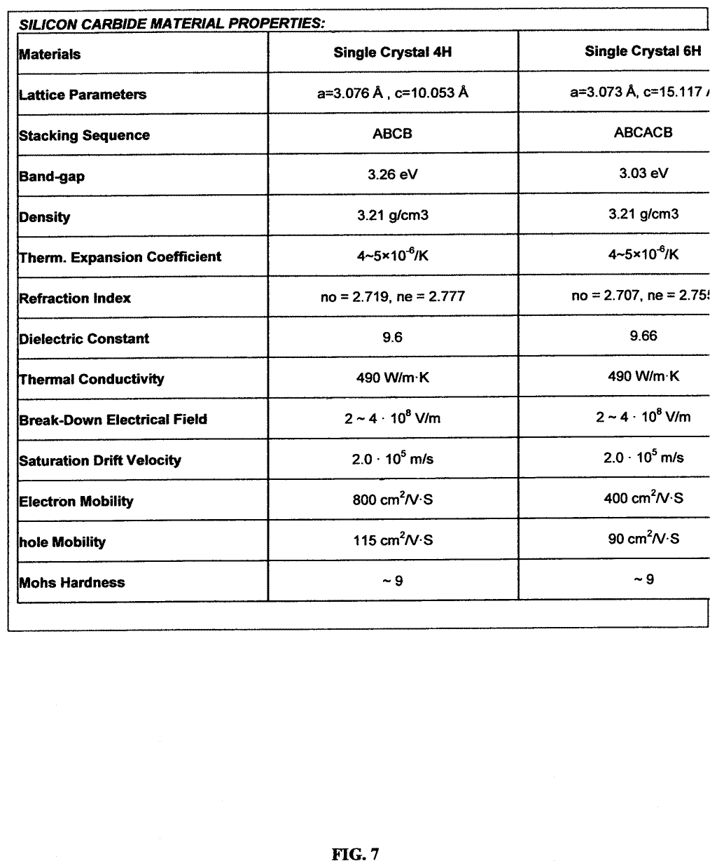

FIG. 7 shows the characteristics of poly types of commercially available Silicon Carbide wafers. The single crystalline wafer of Silicon Carbide, poly types 4H and 6H are available in 2, 3 and 4-inch diameter and 250 to 350 pm thickness. The preferred embodiment of the present invention is to use the 6H poly type, 4-inch diameter wafer at 250 μm (0.01 inch) thickness with a band gap of 3.02 eV and a thermal conductivity of 3.7 W/cm K. The desirable dimensional aspect ratio of 1:3,000 can, in certain practices, be obtained by cutting the 0.01-inch thick wafer into 3-inch strips.

In Situ Formation of the Cell's Conductive Surfaces. A fourth unexpected aspect of embodiments of the present invention is that conductive surfaces of hexagonal pattern Graphene, with superconductive electrical properties at ambient temperatures, can be grown by sublimation of Silicon from Silicon Carbide. In this regard, it is noted that Graphene has an excellent conductivity of 2.35×10³ Siemens per meter, at 3-degrees angle of chirality.

The Graphene is grown on the anode hot surface end of the cell and the cathode cold surface end of the Silicon Carbide cell by sublimation of the Silicon to form the hexagonal crystalline Graphene. Graphene, formed by sublimation of Silicon, has the requisite hexagonal crystalline structure onto which is patterned the hexagonal crystalline form of Silicon at locations where the Graphene is formed on the Silicon Carbide.

In one exemplary embodiment of the present invention, 16 pieces are cut from a heavy doped Silicon Carbide wafer, 0.001 inches thick and a 3-inch long strips of C-terminating 6H-SiC are cut with sufficient width to be a 22.5-degrees cord and are arranged to form a 2-inch diameter circle. The pieces can first be cleaned, such as with Acetone and Methanol, followed by dipping in Hydrofluoric acid. The pieces are then loaded into a Chemical Vapor Deposition (CVD) system. The CVD system can first be purged for two cycles with Hydrogen for 5 minutes at 200 Tone, followed by increasing the temperature to 1,200° C. in the hydrogen atmosphere for 30 minutes to accomplish etching. Finally, the temperature can be increased to 1,700° C. in an Argon atmosphere for thirty (30) minutes to accomplish sublimation of the Silicon. At the end of the Graphene growth cycle, the temperature of the CVD system is reduced to room temperature and purged with Argon before removal of the pieces.

A Preferred Embodiment. Almost 200 years have passed since heat was first directly converted into electricity by employing the thermoelectric effect. Twenty years thereafter, it was shown that this effect could be reversed to accomplish cooling. Over 100 years have passed since light was first directly converted into electricity by employing the photoelectric effect.

However, before devices that employ the thermoelectric and photoelectric effect can be competitive with and replace other methods of electric power generation, there must be appropriate materials (M) and best engineering techniques (BET) for utilizing these effects. The present invention provides M and BET solutions in a hybrid system based on both the thermoelectric effect and the photoelectric effect. The systems and methods disclosed herein elevate system efficiencies to multiple times that obtained by previous single-purpose systems that utilize either the thermoelectric effect or the photoelectric effect.

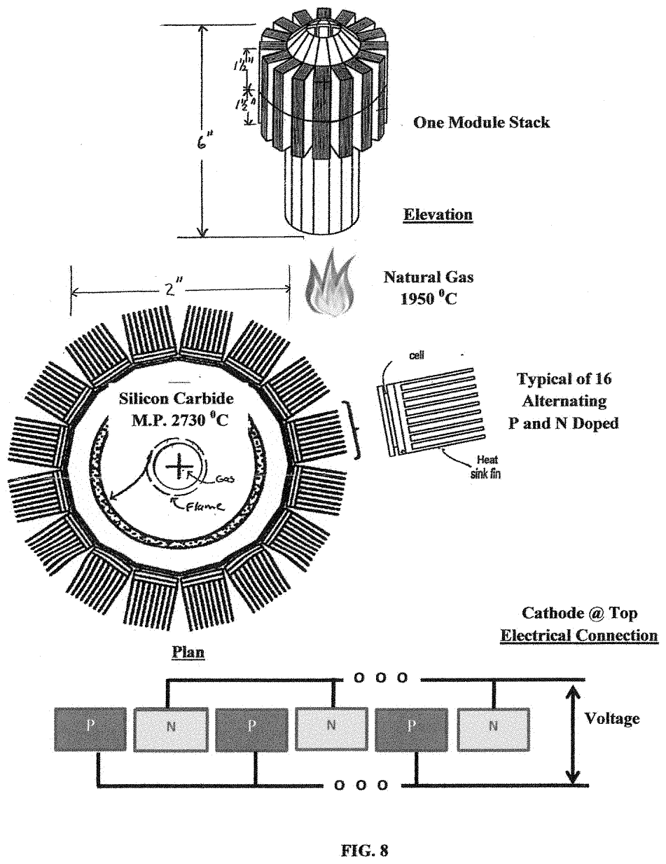

FIG. 8 shows the elements of a preferred embodiment of the present invention for highly efficient thermoelectric power generation. The high melting point of Silicon Carbide of 2730° C. is compatible with the 1,950° C. flame temperature of Natural Gas. Cells are formed from 16 strips of the 6H poly type of Silicon Carbide formed into a cylinder of 2-inch diameter. The strips are alternately doped as p-type and n-type. The cylinder is heated from the bottom by a Silicon Carbide emitter, such as an emitter of a 1.5-inch diameter and a 0.5-inch height. The 16-strips are electrically connected in series at their lower portions and connected p-type to p-type and n-type to n-type at their upper portions. The 2-inch cylinder is cooled by placing finned heat sinks along its long axis to cover the outer surface. This preferred embodiment of the present invention is designed to obtain a 1:3000 aspect ratio to take advantage of the preferred geometry of long and thin cells for generation of electricity by the Seebeck effect. The highly efficient thermoelectric power generation is calculated to achieve thermal efficiency of up to 75%.

With certain details and embodiments of the present invention for Highly Efficient Thermoelectric Power Generation disclosed, it will be appreciated by one skilled in the art that numerous changes and additions could be made thereto without deviating from the spirit or scope of the invention. This is particularly true when one bears in mind that the presently preferred embodiments merely exemplify the broader invention revealed herein. Accordingly, it will be clear that those with major features of the invention in mind could craft embodiments that incorporate those major features while not incorporating all the features included in the preferred embodiments.

Therefore, the claims that will ultimately be employed to protect this invention will define the scope of protection to be afforded to the inventor. Those claims shall be deemed to

What is claimed as deserving the protection of Letters Patent is:

1. A system and method for highly efficient thermoelectric power generation yielding an efficiency of up to 75% and a process for manufacturing such systems by: 1) constructing cells with large length to narrow thickness ratios, such as approaching a 3000:1 aspect ratio; 2) supplying energy incident on the cells by a combustion of natural gas equal to the Earth's opacity spectrum that is filtered out and not available to terrestrial solar cells; 3) using hexagonal crystalline Silicon Carbide semiconductor materials as emitters of a spectrum of energy to create a 1:1 spectral matching as the energy is in turn incident on Silicon Carbide semiconductor material as cells; 4) providing heavy doped cells constructed from the subset of Silicon Carbide crystalline poly types that are hexagonal and arranged in an alternating “p” and “n” configuration; and 5) forming conductive surfaces on the anode hot surface and the cathode cold surface of the Silicon Carbide material cells by sublimation of the silicon to form the hexagonal crystalline carbon, Graphene, with Superconductive conductivity at room temperature at a chirality of 30 degrees, to connect multiple devices in series and in parallel cells that are in turn connected to a terminal to form a power supply.

2. The system, method, and process of claim 1 wherein the Silicon Carbide cells comprise 16 strips cut to form narrow cells from a 0.01-inch thick wafer and long cells with a 3-inch length to achieve a 1:3,000 aspect ratio.

3. The system, method, and process of claim 1 wherein the spectrum incident on the cells, constructed from Silicon Carbide of the same poly type as the emitter, is the infrared spectrum produced by heating of the emitter, to produce congruity of the emission and incident energy spectrums.

4. The system, method, and process of claim 1 wherein the cells are constructed from the subset of Silicon Carbide semiconductor that is crystalline of one of the poly-types that are hexagonal, 2H, 4H, 6H, 8H or 10H and preferably 4H and 6H arranged in an alternating “p” and “n” configuration, Silicon carbide as a semiconductor, which has been heavily doped: p-type by beryllium, boron, aluminum, or gallium and n-type by nitrogen or phosphorus.

5. The system, method, and process of claim 1 wherein conductive surfaces are formed on the anode hot surface, located adjacent to the flame at the bottom of the device, where p-type and n-type cells are electrically connected in parallel, and on the cathode cold surface, located at the top of the device, where p-type and n-type cells are each independently electrically connected in series, are hexagonal crystalline carbon, Graphene, formed by sublimation of the Silicon from Silicon Carbide that exhibits superconductive conductivity at room temperature at a chirality of 30 degrees allowing multiple devices to be electrically connected in series and in parallel cells that are in turn connected to a terminal to form a power supply.
